(19) United States
(12) Patent Application Publication
(10) Pub. No.: US 2019/0207040 A1
(43) Pub. Date: Jul. 4, 2019

(54) CHEMICAL POLISHING OF SOLAR CELL SURFACES AND THE RESULTING STRUCTURES

(71) Applicants: SUNPOWER CORPORATION, San Jose, CA (US); TOTAL SOLAR INTERNATIONAL, Courbevoie (FR)

(72) Inventors: Scott HARRINGTON, Oakland, CA (US); Amada MONTESDEOCA SANTANA, Leuven (BE); Venkatasubramani BALU, Santa Clara, CA (US)

(21) Appl. No.: 15/859,053

(22) Filed: Dec. 29, 2017

(51) Int. Cl. H01L 31/0236; H01L 31/0224; H01L 31/18; H01L 31/068

(52) U.S. Cl. CPC H01L 31/02363; H01L 31/022458; H01L 31/0684; H01L 31/0682; H01L 31/1804

(57) ABSTRACT

Chemical polishing of solar cell surfaces and the resulting structures are described herein. In an example, a method of fabricating a solar cell includes texturizing both first side and second side surfaces of a silicon substrate with a first hydroxide-based etch process. The method also includes reducing a surface roughness factor of the texturized second side surface of the silicon substrate with a second hydroxide-based etch process. The method also includes, subsequent to reducing the surface roughness factor of the texturized second side surface of the silicon substrate, forming emitter regions on the second side surface of the silicon substrate.

### TECHNICAL FIELD

Embodiments of the present disclosure are in the field of renewable energy and, in particular, chemical polishing of solar cell surfaces and the resulting structures.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

### BRIEF DESCRIPTION OF THE DRAWINGS

FIG. 1 is a flowchart listing operations in a method of fabricating a solar cell, in accordance with an embodiment of the present disclosure.

FIGS. 2A-2C illustrate cross-sectional views of various stages in the fabrication of a solar cell, in accordance with an embodiment of the present disclosure.

FIG. 3A includes micrographs of a silicon substrate surface (i) after texturizing with a first hydroxide-based etchant and (ii) after polishing with a second hydroxide-based etchant, in accordance with an embodiment of the present disclosure.

FIG. 3B includes height maps of a silicon substrate surface (i) after texturizing with a first hydroxide-based etchant and (ii) after polishing with a second hydroxide-based etchant, in accordance with an embodiment of the present disclosure.

FIG. 4A illustrates a cross-sectional view of a portion of a back contact solar cell, in accordance with an embodiment of the present disclosure.

FIG. 4B illustrates a cross-sectional view of a portion of another back contact solar cell, in accordance with another embodiment of the present disclosure.

FIG. 5 illustrates a cross-sectional view of a portion of another back contact solar cell, in accordance with another embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. § 112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

Chemical polishing of solar cell surfaces and the resulting structures are described herein. In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as lithography and patterning techniques, are not described in detail in order to not unnecessarily obscure embodiments of the present disclosure. Furthermore, it is to be appreciated that the various embodiments shown in the figures are illustrative representations and are not necessarily drawn to scale.

Disclosed herein are methods of fabricating solar cells. In one embodiment, a method of fabricating a solar cell includes texturizing both first side and second side surfaces of a silicon substrate with a first hydroxide-based etch process. The method also includes reducing a surface roughness factor of the texturized second side surface of the silicon substrate with a second hydroxide-based etch process. The method also includes, subsequent to reducing the surface roughness factor of the texturized second side surface of the silicon substrate, forming emitter regions on the second side surface of the silicon substrate.

Also disclosed herein are solar cells. In one embodiment, a solar cell includes a substrate having a light-receiving surface and a back side surface. The solar cell also includes a plurality of alternating N-type and P-type emitter regions in or above a portion of the back side surface of the substrate. The portion of the back side surface of the substrate has a non-zero surface roughness factor less than a surface roughness factor of the light-receiving surface of the substrate.

In another embodiment, a solar cell includes a substrate having a light-receiving surface and a back side surface. The solar cell also includes a first polycrystalline silicon emitter region of a first conductivity type disposed on a first thin dielectric layer disposed on a portion of the back side surface of the substrate. The portion of the back side surface of the substrate has a non-zero surface roughness factor less than a surface roughness factor of the light-receiving surface of the substrate. The solar cell also includes a second polycrystalline silicon emitter region of a second, different, conductivity type disposed on a second thin dielectric layer disposed in a trench in the back side surface of the substrate. A portion of the second polycrystalline silicon emitter region overlaps a portion of the first polycrystalline silicon emitter region.

In accordance with one or more embodiments of the present disclosure, a relatively low concentration hydroxide (e.g., KOH) etch is used to smooth texturized silicon surfaces. The etch may be utilized cost effectively to reduce back side recombination on wafers that have been texturized on both sides. To provide context, typically, the smoothing of back side surfaces is performed using HF/nitric that is expensive and may be associated with harmful NOx gas, and may be difficult to control. By contrast, embodiments herein may be implemented to deliver less hazardous chemical etching and smoother surfaces as result. In other embodiment, such smoothing may instead or in addition be performed on a wafer front side. In other embodiments, such smoothing is performed during an edge isolation process.

To provide further context, embodiments may be implemented to etch a texturized surface with an alkaline solution (e.g., KOH-based) to remove pyramids and provide a relatively flat silicon surface. Applicants may involve back side contact solar cells, hybrid solar cells, and front side contact solar cells. In certain embodiments, texturizing and subsequent smoothing is performed prior to emitter formation.

Advantages of alkaline polishing approaches described herein as compared to acidic polishing may include one or more of: (1) pyramids may be completely removed, not just rounded and, as such, relative surface area at a back side surface may be reduced to improve passivation, (2) removal of the difficulty in controlling process conditions for an acidic polishing combination of HF/HNO₃, e.g., a small drift in HF/HNO₃ proportion can result in roughening of the surface or out of control etch rate leading to undesirable porous Si formation, (3) removal of HNO₃/HF fumes that are toxic and often require expensive exhaust requirements, and/or (4) reduction of the process from two etch operations to one operation since a HNO₃/HF etch is typically followed by an alkaline etch to remove porous silicon formed during the HNO₃/HF etch.

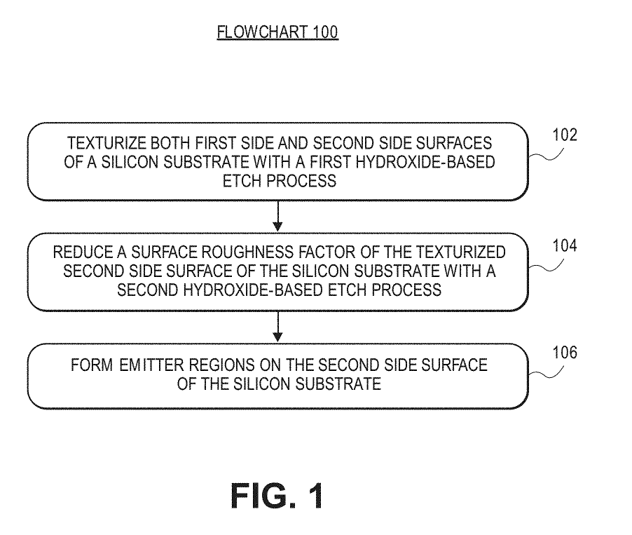

In an exemplary implementation, FIG. 1 is a flowchart 100 listing operations in a method of fabricating a solar cell, in accordance with an embodiment of the present disclosure.

Referring to operation 102 of flowchart 100 of FIG. 1, a method of fabricating a solar cell includes texturizing both first side and second side surfaces of a silicon substrate with a first hydroxide-based etch process. In an embodiment, the first side surface is a front side surface, and the second side surface is a back side surface. In another embodiment, the first side surface is a back side surface, and the second side surface is a front side surface.

In an embodiment, the first hydroxide-based etch process is a first potassium hydroxide-based etch process. In an embodiment, the first hydroxide-based etch process is applied to the silicon substrate in a chemical bath.

Referring to operation 104 of flowchart 100 of FIG. 1, a surface roughness factor of the texturized second side surface of the silicon substrate is reduced with a second hydroxide-based etch process.

In an embodiment, the second hydroxide-based etch process involves exposing the texturized second side surface of the silicon substrate to an aqueous solution of between 5-45 weight percent potassium hydroxide at a temperature between 50-90 degrees Celsius for a during between 1-30 minutes. In a particular such embodiment, the temperature is between 60-85 degrees Celsius.

In another embodiment, the second hydroxide-based etch process involves exposing the texturized second side surface of the silicon substrate to an aqueous solution of between 3-45 weight percent sodium hydroxide at a temperature between 50-90 degrees Celsius for a during between 1-30 minutes. In a particular such embodiment, the temperature is between 60-85 degrees Celsius.

In an embodiment, the first hydroxide-based etch process is a first potassium hydroxide-based etch process, and the second hydroxide-based etch process is a second potassium hydroxide-based etch process. In an embodiment, the second hydroxide-based etch process is applied to the texturized second side surface of the silicon substrate using a spray tool, rollers, or a single-sided etch bath.

In an embodiment, reducing the surface roughness factor of the texturized second side surface of the silicon substrate includes reducing an average surface roughness (Ra) from between 475-525 nanometers to between 175-225 nanometers. In an embodiment, reducing the surface roughness factor of the texturized second side surface of the silicon substrate involves reducing a peak surface roughness (Rp) from between 1600-1700 nanometers to between 400-550 nanometers.

Referring to operation 106 of flowchart 100 of FIG. 1, subsequent to reducing the surface roughness factor of the texturized second side surface of the silicon substrate, emitter regions are formed on the second side surface of the silicon substrate.

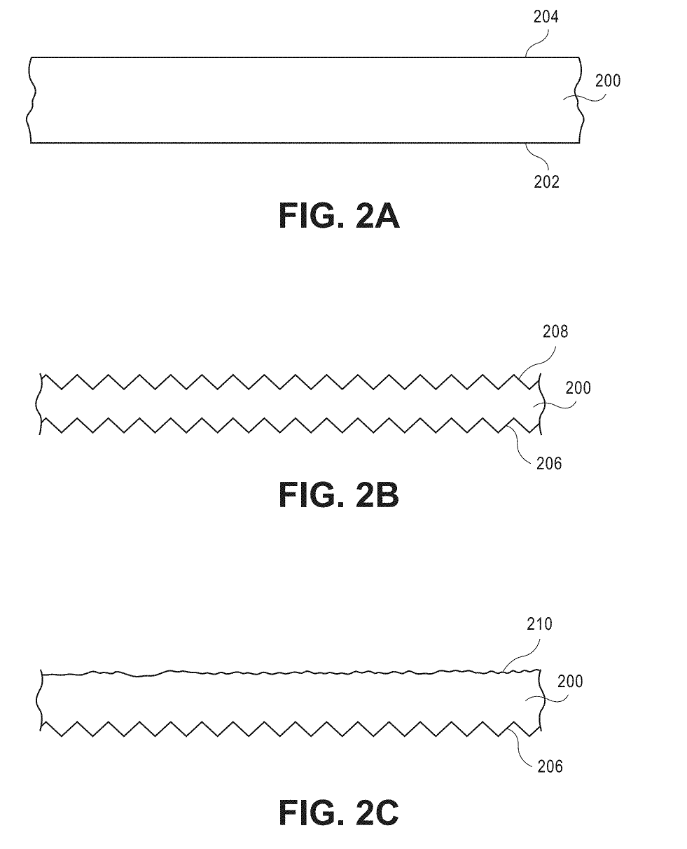

In another exemplary implementation, FIGS. 2A-2C illustrate cross-sectional views of various stages in the fabrication of a solar cell, in accordance with an embodiment of the present disclosure.

Referring to FIG. 2A, a substrate 200 includes a front side surface 202 and a back side surface 204. In an embodiment, the substrate 200 is a monocrystalline silicon substrate. In one such embodiment, the monocrystalline silicon substrate is N-type doped. In an embodiment, the substrate 200 is an as-received substrate following a cutting and polishing process from a starting ingot.

Referring to FIG. 2B, both front side surface 202 and back side surface 206 of substrate 200 of the structure of FIG. 2A are texturized to form texturized front side surface 206 and texturized back side surface 208.

In an embodiment, the texturized front side surface 206 and texturized back side surface 208 are formed using random alkaline texturing which may decrease reflectance and increase the efficiency of the solar cell. Such texturing solutions may include an alkaline etchant, such as potassium hydroxide (KOH), sodium hydroxide (NaOH), or tetramethylammonium hydroxide (TMAH), and, possibly, a surfactant, such as iso-propyl alcohol (IPA) or similar alcohol.

In an embodiment, both front side surface 202 and back side surface 206 of substrate 200 are texturized using a first hydroxide-based etch process. In one such embodiment, the first hydroxide-based etch process is a first potassium hydroxide-based etch process. In one embodiment, the first hydroxide-based etch process is applied to the substrate 200 in a chemical bath.

In a particular embodiment, the first hydroxide-based etch process includes use of an aqueous potassium hydroxide (KOH) solution of approximately 2 weight percent, at a temperature approximately in the range of 50-85 degrees Celsius, for a duration approximately in the range of 10-20 minutes. In an embodiment, the texturizing etch process is followed by a rinse, e.g., with deionized (DI) water.

In an embodiment, prior to performing a texturizing front side surface 202 and back side surface 204 of substrate 200, the substrate 200 is treated with a pre-texturizing wet clean process. In one such embodiment, the pre-texturizing wet clean process includes treatment with an aqueous hydroxide solution, such as but not limited to an aqueous potassium hydroxide (KOH) solution, an aqueous sodium hydroxide (NaOH) solution, or an aqueous tetramethylammonium hydroxide (TMAH) solution. In a specific such embodiment, the pre-texturizing wet clean process includes treatment with an aqueous potassium hydroxide (KOH) solution having a weight percent approximately in the range of 20-45, at a temperature approximately in the range of 60-85 degrees Celsius, for a duration approximately in the range of 60-120 seconds. In another embodiment, the pre-treatment process involves one or more of (1) a dilute mixture of KOH or NaOH with H₂O₂ where is component is present in less than 5% by volume, (2) a process bath of deionized water having ozone dissolved therein, (3) gaseous ozone treatment, and/or (4) a UV cleaning treatment. In an embodiment, the pre-treatment process is followed by a rinse, e.g., with deionized (DI) water.

Referring to FIG. 2C, a surface roughness factor of the texturized back side surface 208 of substrate 200 is reduced to provide a polished back side surface 210.

In an embodiment, the surface roughness factor of the texturized back side surface 208 of substrate 200 is reduced using a second hydroxide-based etch process. In one such embodiment, the second hydroxide-based etch process employs an aqueous solution of between 5-45 weight percent potassium hydroxide at a temperature between 50-90 degrees Celsius for a during between 1-30 minutes. In a particular such embodiment, the temperature is between 60-85 degrees Celsius.

In another such embodiment, the second hydroxide-based etch process employs an aqueous solution of between 3-45 weight percent sodium hydroxide at a temperature between 50-90 degrees Celsius for a during between 1-30 minutes. In a particular such embodiment, the temperature is between 60-85 degrees Celsius.

In an embodiment, the second hydroxide-based etch process is applied only to the texturized back side surface 208 of substrate 200 using a spray tool, rollers, or a single-sided etch bath. In an embodiment, the surface roughness factor reduction process is followed by a rinse, e.g., with deionized (DI) water.

In an embodiment, an average surface roughness (Ra) of the texturized back side surface 208 of substrate 200 is reduced from between 475-525 nanometers to between 175-225 nanometers to provide the polished back side surface 210. In an embodiment, a peak surface roughness (Rp) of the texturized back side surface 208 of substrate 200 is reduced from between 1600-1700 nanometers to between 400-550 nanometers to provide the polished back side surface 210. In an embodiment, the texture pattern and the surface roughness factors of the texturized front side surface 206 of substrate 200 is substantially the same before and after the surface roughness factor of the texturized back side surface 208 of substrate 200 is reduced to provide the polished back side surface 210.

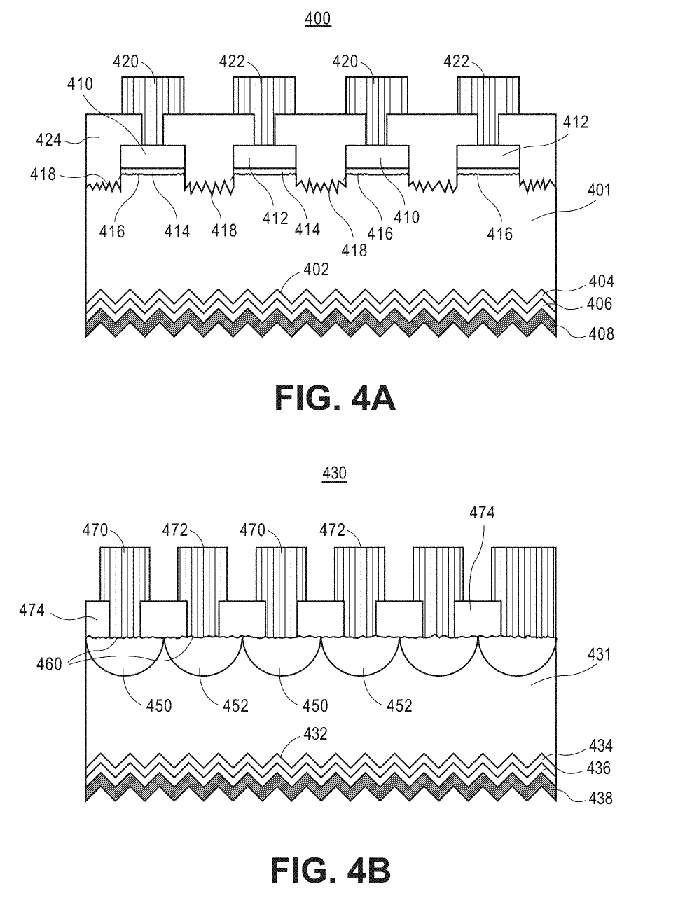

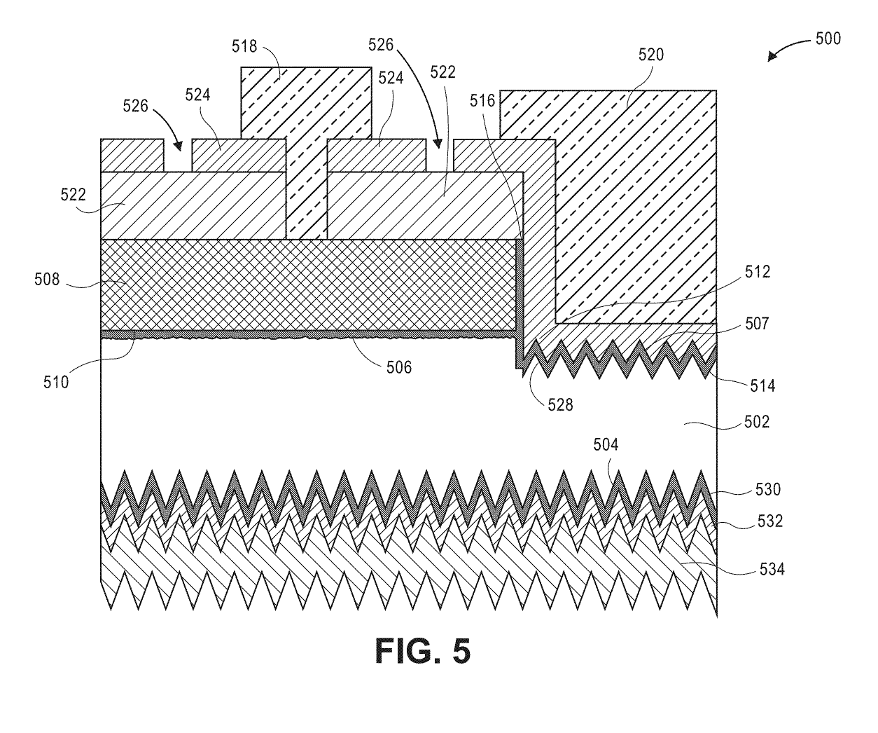

In an embodiment, subsequent to reducing the surface roughness factor of the texturized back side surface 208 of the substrate 200, emitter regions are formed on the polished back side surface 210 of substrate 200. Exemplary solar cell architectures having emitter regions formed on a polished back side surface of a substrate, such as a silicon substrate, are described below in association with FIGS. 4A, 4B and 5.

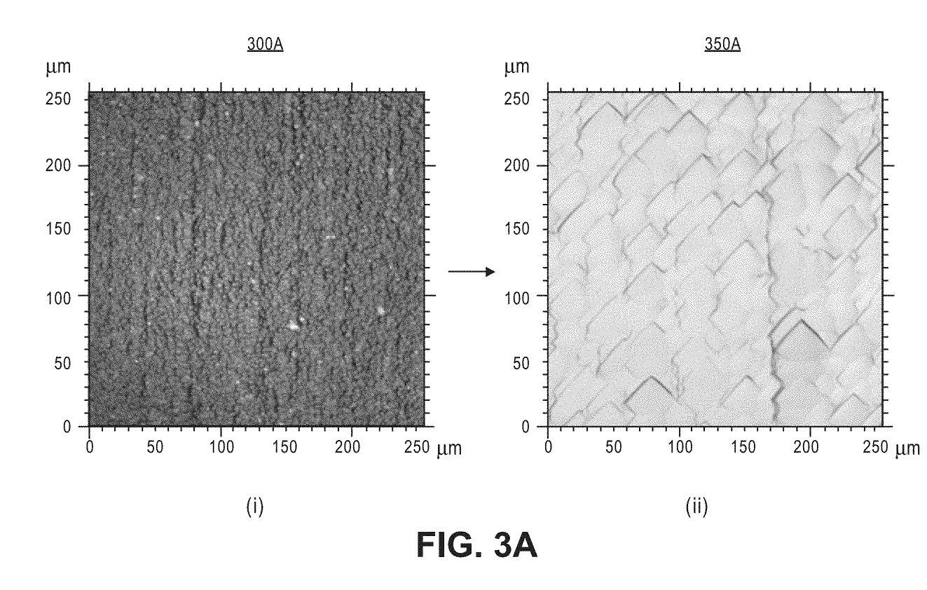

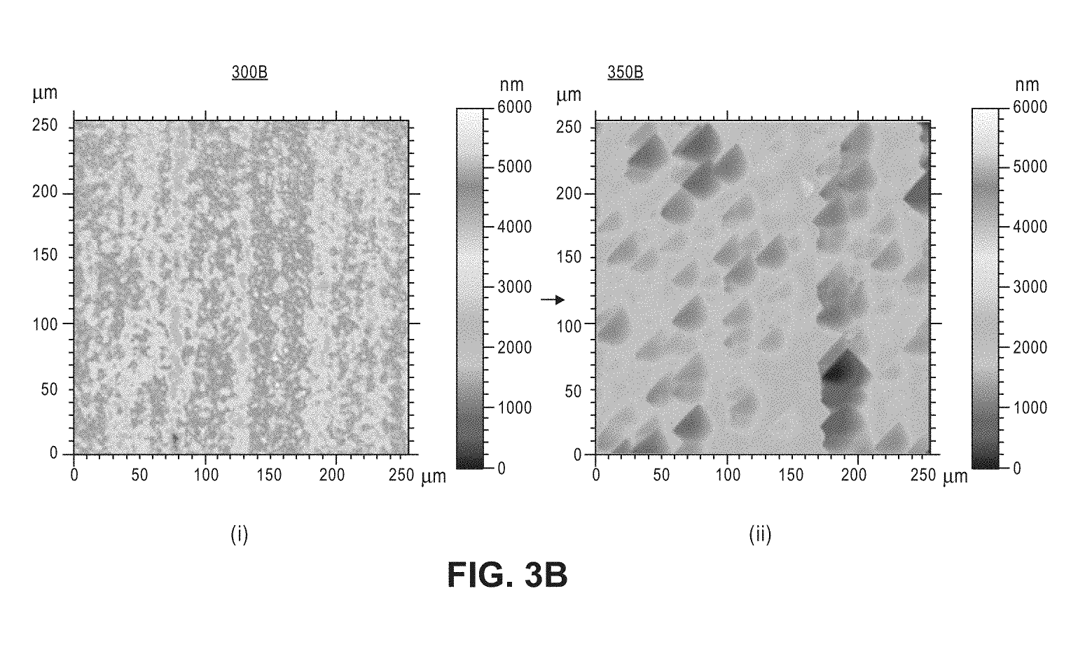

In an exemplary demonstration, FIG. 3A includes micrographs of a silicon substrate surface (i) after texturizing with a first hydroxide-based etchant (micrograph 300A) and (ii) after polishing with a second hydroxide-based etchant (micrograph 350A), in accordance with an embodiment of the present disclosure.

Referring to FIG. 3A, in moving from micrograph 300A to micrograph 350A, roughness reduction is achieved with alkaline polishing. Laser confocal microscopy reveals that the average surface roughness (Ra) of the sample of micrograph 300A is 504 nanometers, and that the peak surface roughness (Rp) is 1655 nanometers. The average surface roughness (Ra) of the sample of micrograph 350A is 209 nanometers, and the peak surface roughness (Rp) is 485 nanometers.

In another exemplary demonstration, FIG. 3B includes height maps of a silicon substrate surface (i) after texturizing with a first hydroxide-based etchant (height map 300B) and (ii) after polishing with a second hydroxide-based etchant (height map 350B), in accordance with an embodiment of the present disclosure.

Referring to FIG. 3B, in moving from height map 300B to height map 350B, roughness reduction is achieved with alkaline polishing. The average surface roughness (Ra) of the sample of height map 300B is 504 nanometers, and the peak surface roughness (Rp) is 1655 nanometers. The average surface roughness (Ra) of the sample of height map 350B is 209 nanometers, and the peak surface roughness (Rp) is 485 nanometers.

As a first exemplary solar cell architecture, FIG. 4A illustrates a cross-sectional view of a portion of a back contact solar cell, in accordance with an embodiment of the present disclosure.

Referring to FIG. 4A, a solar cell 400 includes a substrate 401 having a light-receiving surface 402 and a back side surface opposite the light-receiving surface 402. A plurality of alternating N-type 410 and P-type 412 emitter regions is on a dielectric layer 414 on a portion 416 of the back side surface of the substrate 401. In an embodiment, the portion 416 of the back side surface of the substrate 401 has a non-zero surface roughness factor less than a surface roughness factor of the light-receiving surface 402 of the substrate 401. In an embodiment, the substrate 401 is a monocrystalline silicon substrate. In an embodiment dielectric layer 414 is a silicon oxide layer or silicon dioxide layer having a thickness of approximately 2 nanometers or less.

In an embodiment, the surface roughness factor of the light-receiving surface 402 of the substrate 401 is an average surface roughness (Ra) between 475-525. The non-zero surface roughness factor of the portion 416 of the back side surface of the substrate 401 is an average surface roughness (Ra) between 175-225 nanometers.

In an embodiment, the surface roughness factor of the light-receiving surface 402 of the substrate 401 is a peak surface roughness (Rp) between 1600-1700 nanometers. The non-zero surface roughness factor of the portion 416 of the back side surface of the substrate 401 is a peak surface roughness (Rp) between 400-550 nanometers.

Referring again to FIG. 4A, in an embodiment, a passivating dielectric layer 404, such as a silicon oxide or silicon dioxide layer, is disposed on the light-receiving surface 402 of the substrate 401. An optional intermediate material layer (or layers) 406, such as an amorphous silicon layer, is disposed on the passivating dielectric layer 404. An anti-reflective coating (ARC) layer 408, such as a silicon nitride layer, is disposed on the optional intermediate material layer (or layers) 406, as shown, or is disposed on the passivating dielectric layer 404.

Referring again to FIG. 4A, in an embodiment, trenches 418 are disposed between the alternating N-type 410 and P-type 412 emitter regions. In one such embodiment, trenches 418 have a texturized surface, as is depicted. In a particular embodiment, the non-zero surface roughness factor of the portion 416 of the back side surface of the substrate 401 is less than a surface roughness factor of the texturized surface of the trenches 418.

Referring again to FIG. 4A, in an embodiment, conductive contact structures 420/422 are fabricated by first depositing and patterning an insulating layer 424 to have openings and then forming one or more conductive layers in the openings. As described below, in an embodiment, the conductive contact structures 420/422 include metal and are formed by a deposition, lithographic, and etch approach or, alternatively, a printing or plating process or, alternatively, a foil or wire adhesion process.

As a second exemplary solar cell architecture, FIG. 4B illustrates a cross-sectional view of a portion of another back contact solar cell, in accordance with another embodiment of the present disclosure.

Referring to FIG. 4B, a solar cell 430 includes a substrate 431 having a light-receiving surface 432 and a back side surface 460 opposite the light-receiving surface 432. A plurality of alternating N-type 450 and P-type 452 emitter regions is within the substrate 431 at the back side surface 460 of the substrate 431. In an embodiment, the back side surface 460 of the substrate 431 has a non-zero surface roughness factor less than a surface roughness factor of the light-receiving surface 432 of the substrate 431. In an embodiment, the substrate 431 is a monocrystalline silicon substrate.

In an embodiment, the surface roughness factor of the light-receiving surface 432 of the substrate 431 is an average surface roughness (Ra) between 475-525. The non-zero surface roughness factor of the back side surface 460 of the substrate 431 is an average surface roughness (Ra) between 175-225 nanometers.

In an embodiment, the surface roughness factor of the light-receiving surface 432 of the substrate 431 is a peak surface roughness (Rp) between 1600-1700 nanometers. The non-zero surface roughness factor of the back side surface 460 of the substrate 431 is a peak surface roughness (Rp) between 400-550 nanometers.

Referring again to FIG. 4B, in an embodiment, a passivating dielectric layer 434, such as a silicon oxide or silicon dioxide layer, is disposed on the light-receiving surface 432 of the substrate 431. An optional intermediate material layer (or layers) 436, such as an amorphous silicon layer, is disposed on the passivating dielectric layer 434. An anti-reflective coating (ARC) layer 438, such as a silicon nitride layer, is disposed on the optional intermediate material layer (or layers) 436, as shown, or is disposed on the passivating dielectric layer 434.

Referring again to FIG. 4B, in an embodiment, conductive contact structures 470/472 are fabricated by first depositing and patterning an insulating layer 474 to have openings and then forming one or more conductive layers in the openings. As described below, in an embodiment, the conductive contact structures 470/472 include metal and are formed by a deposition, lithographic, and etch approach or, alternatively, a printing or plating process or, alternatively, a foil or wire adhesion process.

One or more embodiments are directed to hybrid solar cells. To provide context, hybrid or differentiated architectures promise fewer process operations and simpler architecture while providing potential for high efficiencies. In particular, one or more embodiments described herein are directed to forming P+ and N+ polysilicon emitter regions for a solar cell where the respective structures of the P+ and N+ polysilicon emitter regions are different from one another. The resulting structure may provide a lower breakdown voltage and lower power losses associated as compared with other solar cell architectures.

As a third exemplary solar cell architecture, and as an example of a hybrid architecture, FIG. 5 illustrates a cross-sectional view of a portion of another back contact solar cell, in accordance with another embodiment of the present disclosure.

Referring to FIG. 5, a solar cell 500 includes a substrate 502 having a light-receiving surface 504 opposite a back side surface. A first polycrystalline silicon emitter region 508 of a first conductivity type is disposed on a first thin dielectric layer 510 disposed on a portion 506 of the back side surface of the substrate 502. The portion 506 of the back side surface of the substrate 502 has a non-zero surface roughness factor less than a surface roughness factor of the light-receiving surface 504 of the substrate 502. A second polycrystalline silicon emitter region 512 of a second, different, conductivity type is disposed on a second thin dielectric layer 514 disposed in a trench 507 in the back side surface of the substrate 502. A portion of the second polycrystalline silicon emitter region 512 overlaps a portion of the first polycrystalline silicon emitter region 508.

In an embodiment, the substrate 502 is a monocrystalline silicon substrate. In one embodiment, the first conductivity type is P-type, and the second conductivity type is N-type. In another embodiment, the first conductivity type is N-type, and the second conductivity type is P-type.

In an embodiment, the surface roughness factor of the light-receiving surface 504 of the substrate 502 is an average surface roughness (Ra) between 475-525. The non-zero surface roughness factor of the portion 506 of the back side surface of the substrate 502 is an average surface roughness (Ra) between 175-225 nanometers.

In an embodiment, the surface roughness factor of the light-receiving surface 504 of the substrate 502 is a peak surface roughness (Rp) between 1600-1700 nanometers. The non-zero surface roughness factor of the portion 506 of the back side surface of the substrate 502 is a peak surface roughness (Rp) between 400-550 nanometers.

Referring again to FIG. 5, in an embodiment, a third thin dielectric layer 516 is disposed laterally directly between the first polycrystalline silicon emitter region 508 and the second polycrystalline silicon emitter region 512. In an embodiment, a first conductive contact structure 518 is disposed on the first polycrystalline silicon emitter region 508. A second conductive contact structure 520 is disposed on the second polycrystalline silicon emitter region 512.

Referring again to FIG. 5, in an embodiment, the solar cell 500 further includes an insulator layer 522 disposed on the first polycrystalline silicon emitter region 508. The first conductive contact structure 518 is disposed through the insulator layer 522. Additionally, a portion of the second polycrystalline silicon emitter region 512 overlaps the insulator layer 522 but is separate from the first conductive contact structure 518. In an embodiment, an additional polycrystalline silicon layer 524 of the second conductivity type is disposed on the insulator layer 522, and the first conductive contact structure 518 is disposed through the polycrystalline silicon layer 524 and through the insulator layer 522, as is depicted in FIG. 5. In one such embodiment, the additional polycrystalline silicon layer 524 and the second polycrystalline silicon emitter region 512 are formed from a same layer that is blanket deposited and then scribed to provide scribe lines 526 therein.

Referring again to FIG. 5, in an embodiment, the trench 507 has a texturized surface 528. In one such embodiment, the second polycrystalline silicon emitter region 512 and the second thin dielectric layer 514 are conformal with the texturized surface 528, as is depicted in FIG. 5. In a particular embodiment, the non-zero surface roughness factor of the portion 506 of the back side surface of the substrate 502 is less than a surface roughness factor of the texturized surface 528 of the trench 507.

Referring again to FIG. 5, in an embodiment, the solar cell 500 further includes a fourth thin dielectric layer 530 disposed on the light-receiving surface 504 of the substrate 502. An N-type polycrystalline silicon layer 532 is disposed on the fourth thin dielectric layer 532. An anti-reflective coating (ARC) layer 534, such as a layer of silicon nitride, is disposed on the N-type polycrystalline silicon layer 532. In one such embodiment, the fourth thin dielectric layer 532 is formed by essentially the same process used to form the second thin dielectric layer 514.

In an embodiment, the substrate 502 is an N-type monocrystalline silicon substrate. In an embodiment, the first thin dielectric layer 510, the second thin dielectric layer 514 and the third thin dielectric layer 516 include silicon dioxide. However, in another embodiment, the first thin dielectric layer 510 and the second thin dielectric layer 514 include silicon dioxide, while the third thin dielectric layer 516 includes silicon nitride. In an embodiment, insulator layer 522 includes silicon dioxide.

Referring to FIGS. 4A, 4B and 5, in an embodiment, the fabrication of the conductive contacts 420/422 or 470/472 or 518/520 involves the inclusion of one or more sputtered, plated or bonded conductive layers. In an embodiment, the conductive contacts 420/422 or 470/472 or 518/520 are formed by first forming a metal seed layer on the exposed portions of the respective emitter regions (e.g., the exposed portions of the above described P-type or N-type polycrystalline silicon layers). In one such embodiment, a mask is first formed to expose only select portions of the respective emitter regions in order to direct the metal seed layer formation to restricted locations.

In an embodiment, the metal seed layer is an aluminum-based metal seed layer. In an embodiment, the metal seed layer includes a layer having a thickness approximately in the range of 0.05 to 20 microns and includes aluminum in an amount greater than approximately 90 atomic %. In an embodiment, the metal seed layer is deposited as a blanket layer which is later patterned, e.g., thus using a deposition, lithographic, and etch approach. In another embodiment, the metal seed layer is deposited as patterned layer. In one such embodiment, the patterned metal seed layer is deposited by printing the patterned metal seed layer.

In an embodiment, contact formation further includes forming a metal layer by plating on the metal seed layer to form the conductive contacts 420/422 or 470/472 or 518/520. In an embodiment, the metal layer is a copper layer. Accordingly, in an embodiment, the conductive contacts 420/422 or 470/472 or 518/520 are formed by first forming a metal seed layer and then performing an electroplating process.

In another embodiment, the conductive contacts 420/422 or 470/472 or 518/520 are formed by printing a paste. The paste may be composed of a solvent and the aluminum/silicon (Al/Si) alloy particles. A subsequent electroplating or electroless-plating process may then be performed. The paste may be formed in addition to, or in place of, the metal seed layer.

In another embodiment, the conductive contacts 420/422 or 470/472 or 518/520 are formed by first forming the metal seed layer and then adhering a metal foil layer to the metal seed layer. In one such embodiment, the metal foil is an aluminum (Al) foil having a thickness approximately in the range of 5-100 microns. In one embodiment, the Al foil is an aluminum alloy foil including aluminum and second element such as, but not limited to, copper, manganese, silicon, magnesium, zinc, tin, lithium, or combinations thereof. In one embodiment, the Al foil is a temper grade foil such as, but not limited to, F-grade (as fabricated), O-grade (full soft), H-grade (strain hardened) or T-grade (heat treated). In one embodiment, the aluminum foil is an anodized aluminum foil. In an embodiment, the metal foil is welded to the metal seed layer. The metal foil may subsequently be patterned, e.g., by laser ablation and/or etching.

In another embodiment, a metal wire is formed on the metal seed layer. In one such embodiment, the wire is an aluminum (Al) or copper (Cu) wire. In an embodiment, the metal wire is welded to the metal seed layer.

It is to be appreciated that one or more processes described above may be implemented to fabricate a solar cell. The above described processes may be implemented in their entirety or portions of the one or more processes described above may be implemented to fabricate a solar cell.

Although certain materials are described specifically with reference to above described embodiments, some materials may be readily substituted with others with such embodiments remaining within the spirit and scope of embodiments of the present disclosure. For example, in an embodiment, a different material substrate, such as a group III-V material substrate, can be used instead of a silicon substrate. Furthermore, it is to be appreciated that, where the ordering of N+ and then P+ type doping is described specifically for emitter regions on a back surface of a solar cell, other embodiments contemplated include the opposite ordering of conductivity type, e.g., N+ and then P+ type doping, respectively. In other embodiments, a P-type doped substrate is used in place of an N-type doped substrate. In other embodiments, a doping window used to dope the substrate is a relatively large doping window. Additionally, although reference is made significantly to back contact solar cell arrangements, it is to be appreciated that approaches described herein may have application to front contact solar cells as well. In other embodiments, the above described approaches can be applicable to manufacturing of other than solar cells. For example, manufacturing of light emitting diode (LEDs) may benefit from approaches described herein.

Furthermore, in an embodiment, a cluster chemical vapor deposition (CVD) tool can be used to combine many of the above described process operations in a single pass in a process tool. For example, in one such embodiment, up to four distinct CVD operations and an RTP operation can be performed in a single pass in a cluster tool. The CVD operations can includes depositions of layers such as the above described back side P+ polysilicon layer, both front side and back side N+ polysilicon layers, and the ARC layer. In one embodiment, the cluster CVD tool is a cluster plasma enhanced chemical vapor deposition (PECVD) tool.

Thus, chemical polishing of solar cell surfaces and the resulting structures have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A method of fabricating a solar cell, the method comprising:
texturizing both first side and second side surfaces of a silicon substrate with a first hydroxide-based etch process;
reducing a surface roughness factor of the texturized second side surface of the silicon substrate with a second hydroxide-based etch process; and
subsequent to reducing the surface roughness factor of the texturized second side surface of the silicon substrate, forming emitter regions on the second side surface of the silicon substrate.

2. The method of claim 1, wherein the second hydroxide-based etch process comprises exposing the texturized second side surface of the silicon substrate to an aqueous solution of between 5-45 weight percent potassium hydroxide at a temperature between 50-90 degrees Celsius for a during between 1-30 minutes.

3. The method of claim 1, wherein the second hydroxide-based etch process comprises exposing the texturized second side surface of the silicon substrate to an aqueous solution of between 3-45 weight percent sodium hydroxide at a temperature between 50-90 degrees Celsius for a during between 1-30 minutes.

4. The method of claim 1, wherein the first hydroxide-based etch process is a first potassium hydroxide-based etch process, and the second hydroxide-based etch process is a second potassium hydroxide-based etch process.

5. The method of claim 1, wherein the second hydroxide-based etch process is applied to the texturized second side surface of the silicon substrate using a spray tool, rollers, or a single-sided etch bath.

6. The method of claim 5, wherein the first hydroxide-based etch process is applied to the silicon substrate in a chemical bath.

7. The method of claim 1, wherein reducing the surface roughness factor of the texturized second side surface of the silicon substrate comprises reducing an average surface roughness (Ra) from between 475-525 nanometers to between 175-225 nanometers.

8. The method of claim 1, wherein reducing the surface roughness factor of the texturized second side surface of the silicon substrate comprises reducing a peak surface roughness (Rp) from between 1600-1700 nanometers to between 400-550 nanometers.

9. The method of claim 1, wherein the first side surface is a front side surface and the second side surface is a back side surface.

10. A solar cell, comprising:
a substrate having a light-receiving surface and a back side surface; and
a plurality of alternating N-type and P-type emitter regions in or above a portion of the back side surface of the substrate, wherein the portion of the back side surface of the substrate has a non-zero surface roughness factor less than a surface roughness factor of the light-receiving surface of the substrate.

11. The solar cell of claim 10, wherein the surface roughness factor of the light-receiving surface of the substrate is an average surface roughness (Ra) between 475-525, and wherein the non-zero surface roughness factor of the portion of the back side surface of the substrate is an average surface roughness (Ra) between 175-225 nanometers.

12. The solar cell of claim 10, wherein the surface roughness factor of the light-receiving surface of the substrate is a peak surface roughness (Rp) between 1600-1700 nanometers, and wherein the non-zero surface roughness factor of the portion of the back side surface of the substrate is a peak surface roughness (Rp) between 400-550 nanometers.

13. The solar cell of claim 10, wherein the substrate is a monocrystalline silicon substrate.

14. The solar cell of claim 10, wherein the plurality of alternating N-type and P-type emitter regions is in the portion of the back side surface of the substrate.

15. The solar cell of claim 10, wherein the plurality of alternating N-type and P-type emitter regions is on a dielectric layer on the portion of the back side surface of the substrate.

16. A solar cell, comprising:
a substrate having a light-receiving surface and a back side surface;
a first polycrystalline silicon emitter region of a first conductivity type disposed on a first thin dielectric layer disposed on a portion of the back side surface of the substrate, wherein the portion of the back side surface of the substrate has a non-zero surface roughness factor less than a surface roughness factor of the light-receiving surface of the substrate; and
a second polycrystalline silicon emitter region of a second, different, conductivity type disposed on a second thin dielectric layer disposed in a trench in the back side surface of the substrate, wherein a portion of the second polycrystalline silicon emitter region overlaps a portion of the first polycrystalline silicon emitter region.

17. The solar cell of claim 16, wherein the surface roughness factor of the light-receiving surface of the substrate is an average surface roughness (Ra) between 475-525, and wherein the non-zero surface roughness factor of the portion of the back side surface of the substrate is an average surface roughness (Ra) between 175-225 nanometers.

18. The solar cell of claim 16, wherein the surface roughness factor of the light-receiving surface of the substrate is a peak surface roughness (Rp) between 1600-1700 nanometers, and wherein the non-zero surface roughness factor of the portion of the back side surface of the substrate is a peak surface roughness (Rp) between 400-550 nanometers.

19. The solar cell of claim 16, wherein the substrate is a monocrystalline silicon substrate.

20. The solar cell of claim 16, wherein the first conductivity type is P-type, and the second conductivity type is N-type.
